(19) United States
(12) Patent Application Publication
(10) Pub. No.: US 2026/0136718 A1
(43) Pub. Date: May 14, 2026

(54) LIGHT EMITTING ELEMENT AND MANUFACTURING METHOD THEREFOR

(71) Applicants: HGC (WUHAN) TECHNOLOGY CO., LTD, Wuhan (CN); HGC (ZHANGJIAGANG) SEMICONDUCTOR CO., LTD, Suzhou (CN)

(72) Inventors: Leimeng SUN, Wuhan (CN); Xiaoli XU, Wuhan (CN); Fang LIU, Wuhan (CN)

(21) Appl. No.: 18/704,595

(22) PCT Filed: Jan. 19, 2023
(86) PCT No.: PCT/CN2023/073196

§ 371 Date: Apr. 25, 2024

(30) Foreign Application Priority Data
Nov. 30, 2022 (CN) 202211519002.2

(51) Int. Cl. H10H 20/831; H10H 20/01; H10H 20/832

(52) U.S. Cl. CPC H10H 20/8316; H10H 20/032; H10H 20/835

(57) ABSTRACT

The present disclosure provides a light emitting element. Pads of the light emitting element includes two N-type pads and one P-type pad. The P-type pad is located between the two N-type pads. The area proportion of the N-type pad is more than that of the P-type pad, and a plurality of N type holes are uniformly provided at an end surface of each of the N-type pads. The area proportion of the N-type pad is larger, the distribution of the N-type hole is wider, so that more current channels will be formed between the P electrode and the N electrode, and the current spreading between the P electrode and the N electrode is more sufficient, thereby reducing the voltage between the P electrode and the N electrode. In addition, the present disclosure also provides a manufacturing method for the light emitting element.

### TECHNICAL FIELD

The present disclosure relates to a field of semiconductor technologies, and more particularly, to a light emitting element and a manufacturing method therefor.

### BACKGROUND

Alight emitting diode, which is briefly referred to as LED, is a semiconductor light emitting device, and has optoelectronic performance characteristics such as low energy consumption, long service life, good stability, fast response, stable light emitting wavelength, and so on. Therefore, the LED has wide applications in the fields of lighting, home appliances, display screens, indicator lights, and so on.

Compared with a conventional front-loading structure, a flip-chip LED chip has advantages in terms of heat dissipation, luminous efficiency and the like, and therefore, the flip-chip LED chip is becoming increasingly widely used. In conventional flip-chips, P and N contact materials and GaN can form a good ohmic contact. However, in practical applications, a high-power chip of an automotive grade has higher and higher requirements on a low voltage, and only a fine adjustment can be performed on a voltage by adjusting the contact materials, and thus the voltage cannot be substantially reduced. In addition, during a process of reducing the voltage, the adjustment on the structure also causes a loss to the brightness, and cannot meet requirements of a market.

### SUMMARY

A main object of the present disclosure is to provide a light emitting element and a manufacturing method therefor, which are intended to solve the technical problem in the prior art that a voltage cannot be reduced substantially, and at the same time, the brightness will be lost due to the adjustment on the structure during a process of reducing the voltage.

In order to achieve the above object, the present disclosure provides a light emitting element, including a substrate, and a light emitting structure, a current spreading layer, a passivation layer, a reflective layer, a barrier layer, an insulating layer and a pad which are sequentially grown on the substrate;
the pad includes two N-type pads and one P-type pad, the P-type pad being located between the two N-type pads, an area proportion of the N-type pad is more than that of the P-type pad, and a plurality of N-type holes are uniformly arranged at an end surface of each of the N-type pads, so as to provide more current channels between the P electrode and the N electrode, so that current spreading between the P electrode and the N electrode is sufficient, thereby reducing a voltage between the P electrode and the N electrode.

Optionally, the plurality of N-type holes are arranged in a plurality of columns at an end surface of the N-type pad, and the N-type holes in two adjacent columns are arranged in a staggered manner, so that the N-type holes are distributed uniformly at the end surface of the N-type pad.

Optionally, the area proportion of the N-type pad is more than 10 times of that of the P-type pad, so that a plurality of N-type holes can be provided at the end surface of the N-type pad to increase provide more current channels between the P electrode and the N electrode.

Optionally, apertures of the current spreading layer and apertures of the passivation layer are arranged in a staggered manner, so as to improve the brightness.

Optionally, a component of reflective metal for forming the reflective layer includes Ag alloy and 2%-5% Pt component for improving brightness.

Further, in order to achieve the above object, the present application provides a manufacturing method for a light emitting element, including the following steps of:
sequentially growing an N-type semiconductor layer, an active layer and a P-type semiconductor layer on a substrate so as to form an epitaxial layer;
etching an isolation channel between adjacent chiplets, so that each chiplet is completely isolated on the epitaxial layer, thereby forming separate units;
etching a groove extending to the N-type semiconductor layer on the P-type semiconductor layer by means of inductive coupling plasma etching process, so as to form an N-type conductive region;
forming a current spreading layer on the P-type semiconductor layer;
forming a passivation layer on the current spreading layer;
forming a reflective layer on the passivation layer;
forming a barrier layer on the reflective layer;
forming an insulating layer on the barrier layer;
depositing an N-type pad and a P-type pad.

Optionally, the step of forming a passivation layer (103) on the current spreading layer includes:
firstly evaporating an SiO₂ film layer, and then evaporating an TiO₂ film layer on the SiO₂ film layer;
repeating the evaporating process until SiO₂/TiO₂ laminated layer having a thickness of 1000 Å-2000 Å is formed;
dry etching the SiO₂/TiO₂ laminated layer through an ICP dry etching process, until etching to the lowermost TiO₂ layer; and
wet etching an SiO₂ film layer at the lowermost layer of the SiO₂/TiO₂ laminated layer through a BOE wet etching process.

Optionally, the step of forming the reflective layer (104) on the passivation layer includes:
coating a layer of reflective metal on the passivation layer by a magnetron sputtering process or a vacuum evaporation coating process;
while coating the reflective metal, continuously depositing a Ti/Pt or TiW film layer on an upper layer and covering the reflective metal.

Optionally, the step of forming an insulating layer (106) on the barrier layer includes:
depositing a passivation film layer using a plasma enhanced vapor deposition process at 250° C. to 300° C.;
depositing a reflective layer of Al metal with a thickness of 500 Å-1000 Å on the passivation film layer;
depositing the passivation film layer on the reflective layer of Al metal;
making an aperture on the passivation film layer by etching through the yellow light uniform photoresist exposure and development process.

Optionally, the step of depositing an N-type pad (1071) and a P-type pad includes:
patterning the pad by using the yellow light uniform photoresist exposure and development process;
removing negative adhesive base film by using an Asher process;
depositing Cr/Pt/Ni/Pt/Ni/AuSn using an E-Beam device after a wafer source is cleaned by spinning; and
removing photoresist using an alkaline degumming liquid.

According to the technical solution of the present disclosure, the light emitting element includes the substrate, and the light emitting structure, the current spreading layer, the passivation layer, the reflective layer, the barrier layer, the insulating layer and the pad which are sequentially grown on the substrate. The pad includes two N-type pads and one P-type pad, the P-type pad being located between the two N-type pads, an area proportion of the N-type pad is greater than that of the P-type pad, and a plurality of N-type holes are uniformly arranged at an end surface of each of the N-type pads, so as to provide more current channels between the P electrode and the N electrode, so that current spreading between the P electrode and the N electrode is sufficient, thereby reducing voltage between the P electrode and the N electrode. Further, the area of the N-type pad is far greater than the area of the P-type pad, so that the area proportion of the N-type pad is improved. The area proportion of the N-type pad is larger, the distribution of the N-type hole is wider, and the contact area of the N electrode is larger, so that more current channels will be formed between the P electrode and the N electrode, and the current spreading between the P electrode and the N electrode is more sufficient, thereby reducing the voltage between the P electrode and the N electrode.

### BRIEF DESCRIPTION OF THE DRAWINGS

To describe the technical solutions in the embodiments of the present disclosure or in the prior art more clearly, the following briefly introduces the accompanying drawings required for describing the embodiments or the prior art. Apparently, the accompanying drawings in the following description show merely some embodiments of the present disclosure, and other drawings may also be obtained according to structures shown in these drawings without creative efforts.

FIG. 1 is a schematic structural view of a light emitting element according to an embodiment of the present disclosure.

FIG. 2 is a top view of the light emitting element in FIG. 1.

FIG. 3 is a structural schematic diagram of an N-type conductive region of a light emitting element in FIG. 1.

FIG. 4 is a structural schematic diagram of a current spreading layer of the light emitting element in FIG. 1.

FIG. 5 is a structural schematic diagram of a passivation layer of a light emitting element in FIG. 1.

FIG. 6 is a structural schematic diagram of a reflective layer of a light emitting element in FIG. 1.

FIG. 7 is a structural schematic diagram of a barrier layer of a light emitting element in FIG. 1.

FIG. 8 is a schematic structural view of an insulating layer of a light emitting element in FIG. 1.

FIG. 9 is a structural schematic diagram of a pad of a light emitting element in FIG. 1.

FIG. 10 is a flowchart of a manufacturing method for a light emitting element according to an embodiment of the present disclosure.

### REFERENCE NUMERALS

| Reference Numeral | Name |
|---|---|
| 100 | light emitting element |
| 101 | substrate |
| 102 | current spreading layer |
| 103 | passivation layer |
| 104 | reflective layer |
| 105 | barrier layer |
| 106 | insulating layer |
| 107 | pad |
| 1071 | N-type pad |
| 1072 | P-type pad |
| 1073 | N-type hole |

Implementation of the objectives, functional features, and advantages of the present disclosure are further described with reference to the accompanying drawings in combination with embodiments.

### DETAILED DESCRIPTION OF THE EMBODIMENTS

To make the objectives, technical solutions, and advantages of the present disclosure clearer, the following further describes the present disclosure in detail with reference to the accompanying drawings and specific embodiments. The technical solutions of the present disclosure are clearly and completely described. Apparently, the described embodiments are a part rather than all of the embodiments of the present disclosure. All other embodiments obtained by persons of ordinary skill in the art based on the embodiments of the present disclosure without creative efforts shall belong to the scope of protection of the present disclosure.

Hereinafter, embodiments of the present disclosure will be described with reference to the accompanying drawings, but it should be understood that these descriptions are only exemplary and are not intended to limit the scope of the present disclosure. In the following detailed description, for purposes of explanation, numerous specific details are set forth in order to provide a thorough understanding of embodiments of the disclosure. It will be evident, however, that one or more embodiments may be practiced without these specific details. In addition, in the following description, descriptions of well-known structures and techniques are omitted to avoid unnecessarily obscuring the concepts of the present disclosure.

The terminology used herein is for the purpose of describing particular embodiments only and is not intended to be limiting of the disclosure. The terms “comprising”, “including”, and the like, as used herein, indicate the presence of stated features, steps, operations, and/or components, but do not preclude the presence or addition of one or more other features, steps, operations, or components.

All terms (including technical and scientific terms) used herein have the meaning commonly understood by one of skill in the art, unless defined otherwise. It should be noted that the terms used herein should be interpreted as having a meaning that is consistent with the context of this specification, and should not be interpreted in an idealized or overly stereotyped manner.

In those instances where a phrase similar to “at least one of A, B, and C, etc.” is used, it should be generally interpreted within the meaning of the phrase as would normally occur to those skilled in the art (e. g., “a system having at least one of A, B, and C” should include, but not be limited to, systems having A alone, B alone, C alone, A and B, A and C, B and C, and/or A, B, C, etc.). In those instances where a phrase similar to “at least one of A, B, or C, etc.” is used, such phrase generally should be interpreted in accordance with the ordinary skill in the art (e. g., “a system having at least one of A, B, or C” should include, but not be limited to systems having A alone, B alone, C alone, A and B together, A and C together, B and C together, and/or A, B, C together, etc.).

It should be noted that, if the embodiments of the present disclosure involve a directional indication, the directional indication is only used to explain a relative position relationship, a motion condition, and the like between components in a certain specific posture, and if the specific posture changes, the directional indication changes accordingly.

In addition, if there are descriptions related to “first” and “second” in the embodiments of the present disclosure, the descriptions of “first” and “second” are only for description purposes, and cannot be understood as indicating or implying the relative importance thereof or implicitly indicating the number of indicated technical features. Thus, the features defined by “first” and “second” may explicitly or implicitly include at least one of the features. In addition, the meaning of “and/or” appearing in the full text includes three parallel solutions. Taking “A and/or B” as an example, the solution includes an A solution, a B solution, or a solution that both A and B satisfy. In addition, the technical solutions in the embodiments may be combined with each other, but they must be based on the implementation of a person of ordinary skill in the art. When the combination of the technical solutions is contradictory or cannot be implemented, it should be considered that the combination of the technical solutions does not exist, and is also not within the scope of protection of the present disclosure.

In the description of the present disclosure, it should be noted that, orientation or position relationships indicated by terms such as “upper”, “lower”, “top”, “bottom”, “inner”, “outer” and the like are orientation or position relationships shown based on the accompanying drawings, which are only used to facilitate the description of the present disclosure and simplify the description, rather than indicating or implying that a device or element referred to must have a specific orientation, and be constructed and operated in a specific orientation, and therefore cannot be construed as a limitation to the present disclosure.

In the description of the present disclosure, it should be noted that, unless specified or limited otherwise, the terms “mounted”, “connected”, and “connected” should be understood broadly, and may be, for example, fixed connections, detachable connections, or integral connections; may also be mechanical or electrical connections; may also be direct connections or indirect connections via intervening structures; and may also be inner communications of two elements. The specific meanings of the above terms in the present disclosure can be understood by those skilled in the art according to specific situations.

In addition, in the description of the present disclosure, unless otherwise specified, “a plurality of”, “a plurality of”, or “a plurality of groups” means two or more.

The following clearly and completely describes the technical solutions in the embodiments of the present disclosure with reference to the accompanying drawings in the embodiments of the present disclosure. Apparently, the embodiments to be described are merely a part rather than all of the embodiments of the present disclosure. All other embodiments obtained by persons of ordinary skill in the art based on the embodiments of the present disclosure without creative efforts shall belong to the scope of protection of the present disclosure.

In practical applications, a high-power vehicle-scale chip has higher and higher requirements for a low voltage. By adjusting a contact material, only a voltage can be finely adjusted, and the voltage cannot be reduced significantly. In addition, during a step-down process, the adjustment of a structural bar may cause a loss of brightness. In view of this, the present disclosure provides a light emitting element and a preparation method therefor, which are intended to solve the described problem.

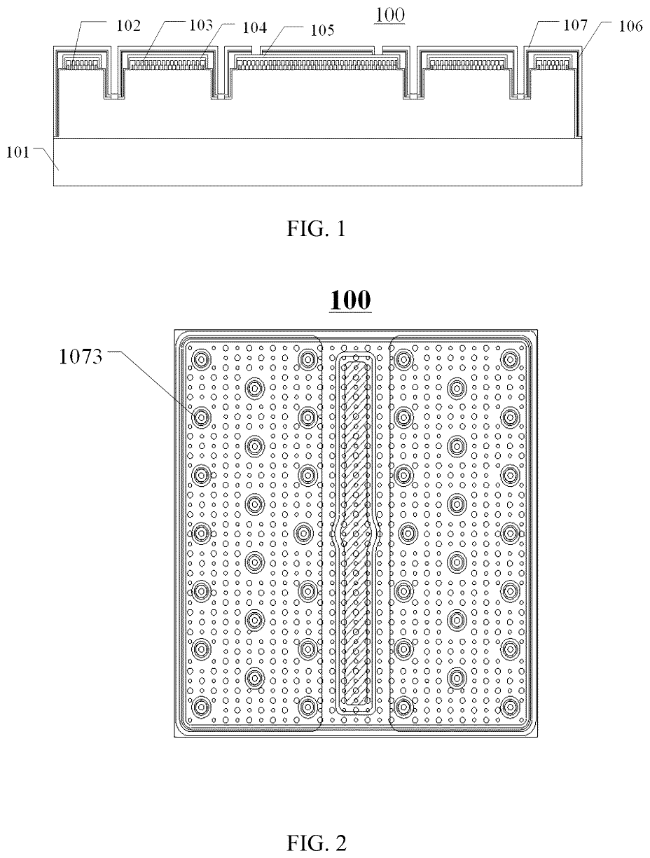

Referring to FIG. 1, FIG. 1 is a schematic diagram of a structure of a light emitting element 100 according to an embodiment of the present disclosure. The light emitting element 100 includes a substrate 101, a light emitting structure, a current spreading layer 102, a passivation layer 103, a reflective layer 104, a barrier layer 105, an insulating layer 106 and a pad 107. A light emitting structure, a current spreading layer 102, a passivation layer 103, a reflective layer 104, a barrier layer 105, an insulating layer 106 and a pad are sequentially grown on a substrate 101.

A substrate material of a semiconductor device is also referred to as a substrate material, and epitaxial layers are all obtained by growing on the substrate material. There are a variety of materials for an LED substrate, and a sapphire substrate is used in the present embodiment, which has the advantages of good chemical stability, no absorption of visible light, and good light transmission.

The light emitting structure includes an N-type semiconductor layer, an active layer and a P-type semiconductor layer sequentially formed on a sapphire substrate. A buffer layer and the light emitting structure are grown on the sapphire substrate by a Metal Organic Chemical Vapor Deposition technique. The light emitting structure includes an N-type semiconductor layer, an active layer and a P-type semiconductor layer which are formed in sequence, and forms an epitaxial layer of a chip. The current spreading layer 102 is formed by depositing an ITO layer on a surface of a P-type semiconductor layer through a magnetron sputtering process, and is annealed to form a P-type ohmic contact. The passivation layer 103 is an SiO₂/TiO₂ laminated layer evaporated on the current spreading layer by using a DBR evaporation device. The reflective layer 104 is formed by depositing reflective metal on the passivation layer by using a magnetron sputtering process or a vacuum evaporation coating process. The barrier layer 105 is a film layer coated on the reflective layer 104 by a vacuum evaporation coating process. The components of the barrier layer 105 mainly include Au, and the remaining components include one or more of Cr/Pt/Ti/Ni/Sn elements. The insulating layer 106 is a film layer deposited on the barrier layer using a plasma enhanced vapor deposition process.

It should be noted that, in the present embodiment, a conventional symmetrical electrode structure design is changed, and a novel asymmetrical electrode structure design is used instead. Specifically, referring to FIG. 2, in this embodiment, the pad 107 includes two N-type pads 1071 and one P-type pad 1072. The two N-type pads 1071 are disposed on two sides, and the P-type pad 1072 is disposed at the center. Compared with the existing structure, the contact area for the N-type pad 1071 is increased, and the distribution of the N-type hole is wider, so that more current channels will be formed between the P electrode and the N electrode, and current spreading between the P electrode and the N electrode is more sufficient, thereby reducing the voltage between the P electrode and the N electrode.

In addition, in the present embodiment, the area proportion of the N-type pad 1071 is set to be more than 10 times of that of the P-type pad 1072. The area covered by the N-type pad 1071 is far greater than that of the P-type pad 1072. The area proportion of the N-type pad 1071 is improved, and the area proportion of the P-region for lamination is reduced. The area proportion of the N-type pad 1071 is larger, the distribution of the N-type hole 1073 is wider, and the contact area for the N-electrode is larger, which further reduces the voltage between the P-electrode and the N-electrode, thereby satisfying more application scenarios.

Further, in this embodiment, the plurality of N-type holes 1073 are arranged in a plurality of columns at an end surface of the N-type pad 1071, and the N-type holes 1073 in two adjacent columns are arranged in a staggered manner, so that the N-type holes 1073 are distributed uniformly at the end surface of the N-type pad 1071. The plurality of N-type holes 1073 are arranged at an end surface of the N-type pad 1071, and three adjacent N-type holes 1073 are arranged as an equilateral triangle. The N-type holes 1073 are designed to be uniformly distributed, which can better optimize current conduction and reduce voltage compared with a conventional non-uniformity arrangement.

Further, referring to FIG. 1, in the present embodiment, the apertures of the current spreading layer 102 and the apertures of the passivation layer 103 are arranged in a staggered manner. A direct contact between The SiO₂/TiO₂ laminated layer and the P semiconductor layer can achieve an optimal effect of ODR reflection, and therefore, designing ITO patterned apertures not only ensures an excellent current spreading, but also increases the contact area between the passivation layer 103 and the P semiconductor layer.

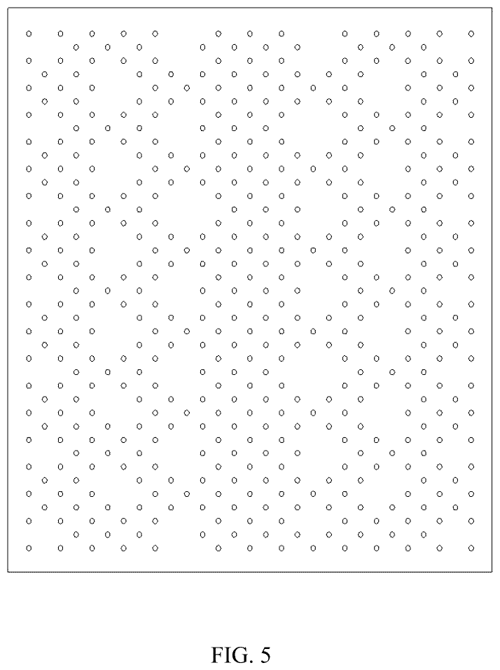

Further, referring to FIG. 5, in this embodiment, the SiO₂/TiO₂ laminated layer in the passivation layer 103 has a thickness of 1000 Å-2000 Å. The passivation layer 103 is evaporated on the current spreading layer by using a DBR evaporation device, and the specific evaporation process of the passivation layer 103 is as follows. Firstly, an SiO₂ film layer is evaporated on the current spreading layer, and then a TiO₂ film layer is evaporated on the SiO₂ film layer, and the above evaporation process is repeated until the SiO₂/TiO₂ laminated layer having a thickness of 1000 Å-2000 Å is formed. The SiO₂/TiO₂ laminated layer growth forms a DBR structure, and at the same time forms an ODR structure with GaN and Ag, which further improves the reflectivity compared with a traditional ODR structure.

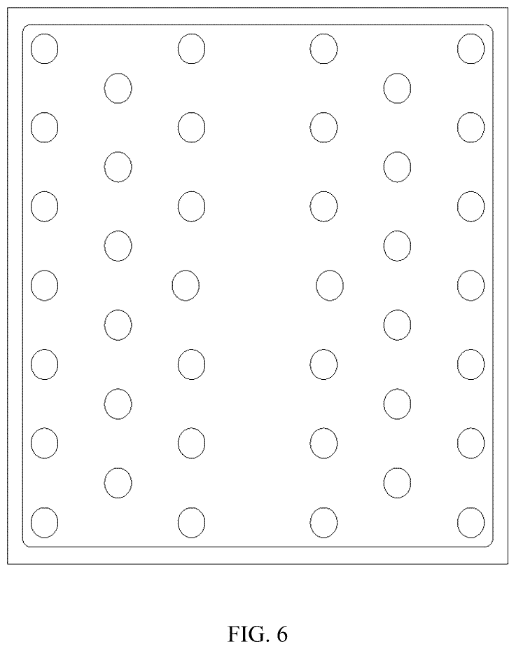

Further, referring to FIG. 6, in the present embodiment, the component of the reflective metal for forming the reflective layer 104 includes Ag alloy and 2%-5% Pt component. In other embodiments, the reflective metal of the reflective layer can also be Al/Rh, etc. as the reflective metal. However, in the present embodiment, the Ag alloy component is preferably selected, and doped with 2%-5% Pt component. The advantage of such a design is that migration of Ag can be reduced, and at the same time, the distance between the reflective layer and the edge of the Mesa is shortened, the area of the reflective layer is increased, and the brightness is improved. In addition, the N-type hole 1073 is filled with an Ag reflective metal, thereby reducing a height difference between the layers of film caused by the N-type hole 1073, reducing a eutectic cavity ratio of a chip package, and improving the reliability of a product.

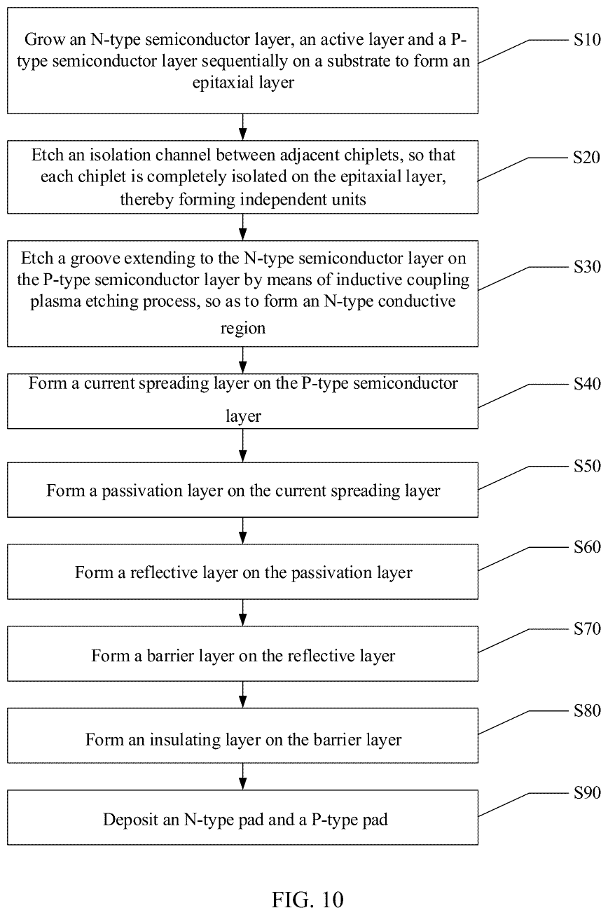

In addition, in order to achieve the above object, the present disclosure also provides a manufacturing method for a light emitting element. Referring to FIG. 10, which is a flowchart of a manufacturing method for a light emitting element according to an embodiment of the present disclosure, the manufacturing method for a light emitting element includes the following steps.

In step S10: an N-type semiconductor layer, an active layer and a P-type semiconductor layer are sequentially grown on a substrate 101 to form an epitaxial layer.

In step S20: an isolation channel is etched between adjacent chiplets, so that each chiplet is completely isolated on the epitaxial layer, thereby forming separate units.

In step S30: a groove extending to the N-type semiconductor layer is etched on the P-type semiconductor layer by means of inductive coupling plasma etching process, so as to form an N-type conductive region.

In step S40: a current spreading layer 102 is formed on the P-type semiconductor layer.

In step S50: a passivation layer 103 is formed on the current spreading layer 102.

In step S60: a reflective layer 104 is formed on the passivation layer 103.

In step S70: a barrier layer 105 is formed on the reflective layer 104.

In step S80: an insulating layer 106 is formed on the barrier layer 105.

In step S90: an N-type pad 1071 and a P-type pad 1072 are deposited.

In this embodiment, a growth substrate 101 is provided, and a buffer layer (not shown in the figure), an N-type semiconductor layer, an active layer and a P-type semiconductor layer are sequentially grown on the growth substrate 101. The N-type semiconductor layer, along with the active layer, and the P-type semiconductor layer together constitute the epitaxial layer, i.e. (a light emitting structure). The growth substrate 101 may be a sapphire substrate, a GaN substrate, a silicon substrate, a silicon carbide substrate, or the like. In this embodiment, the growth substrate 101 is a sapphire substrate, and the materials of the buffer layer, the N-type semiconductor layer and the P-type semiconductor layer are all material of GaN. The buffer layer, the N-type semiconductor layer 21, the active layer 22 and the P-type semiconductor layer 23 may all be formed by a growth method such as Metal Organic Chemical Vapor Deposition (MOCVD) and/or Molecular Beam Epitaxy (MBE).

In step S20, the epitaxial layer structure 2 is deeply etched using an inductive coupling plasma etching process, so as to create isolation channels between adjacent light emitting elements, so that each light emitting element is completely separated on the growth substrate 101, thereby forming independent light emitting element units. The specific depth for etching is determined according to the thickness of the epitaxial layer, and is generally between 6 μm and 7 μm. It should be noted that, in this embodiment, a structure including a plurality of light emitting elements is manufactured through step S10, and then deep etching is performed, so that each light emitting element is completely separated on the growth substrate 101 to form independent light emitting element units. In other embodiments of the present disclosure, a single light emitting element structure may also be formed directly on the growth substrate 101 by step S10.

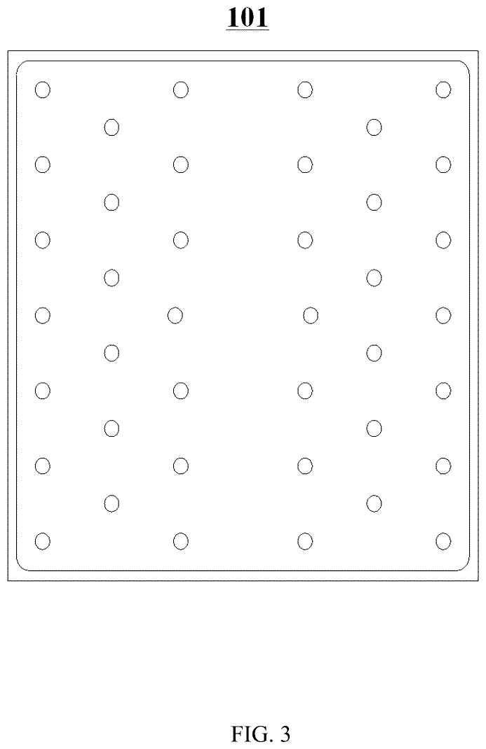

Combined with FIG. 3, in step S30, a groove structure is formed etching through the inductive coupling plasma etching process, and the depth for etching is determined according to the growth thickness of each semiconductor layer, and is generally with a depth of 1 μm-1.5 μm. In this embodiment, N-type conductive apertures are respectively arranged on the periphery of the light emitting element through step S30, so as to form the N-type conductive.

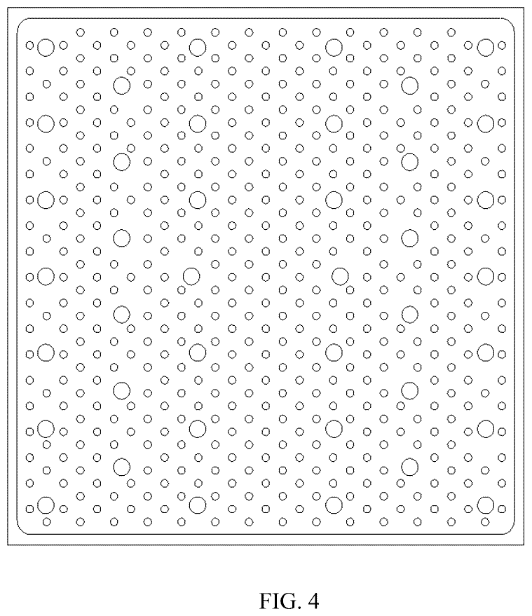

Combined with FIG. 4, in step S40, the ITO layer is deposited on the surface of the P-type semiconductor layer 23 by using the magnetron sputtering process, the deposited thickness is 200 Å-600 Å, the current spreading layer 4 is deposited on the surface of the P-type semiconductor layer 23, and is annealed to form a P-type ohmic contact. The main component of ITO is Indium-Tin Oxide, which is a semiconductor transparent conductive film, and can have the characteristics of low resistivity and high light transmittance at the same time, meeting the requirements of good conductivity and light transmittance. The function of ITO is to enable an electrode to form a good ohmic contact with the epitaxial layer, so that the current diffuses on the surface of the electrode and better passes into the electrode, thereby reducing the voltage. At the same time, the Mg—H bonds in the P-type gallium nitride layer are broke by annealing in an oxygen atmosphere, thereby activating Mg and better forming an ohmic contact.

Combined with FIG. 5, in step S50, a passivation layer 103 is evaporated on the current spreading layer 102 by using the DBR evaporation device. The material of the passivation layer 103 is SiO₂, TiO₂. Specifically, the passivation layer 103 is a laminated deposition film of SiO/TiO₂ with a deposited thickness of 1,000 Å to 2,000 Å, and the deposition temperature is.

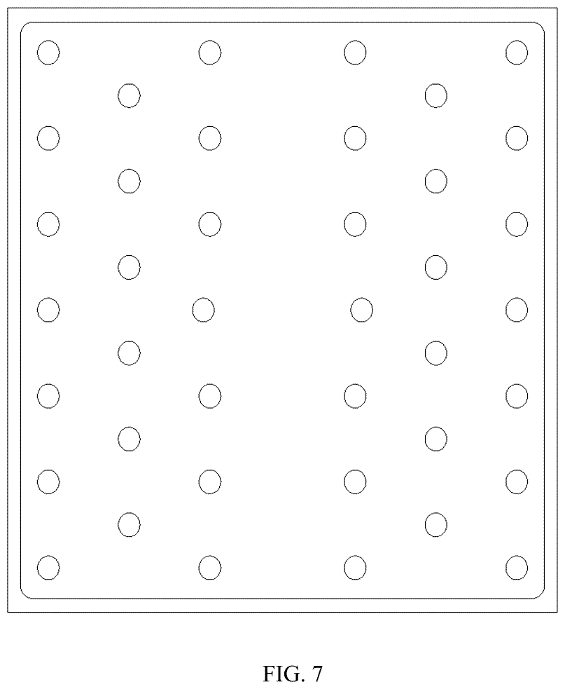

Referring to FIGS. 6 and 7, in Step S60, the reflective layer 104 is formed by depositing a reflective metal on the passivation layer through the magnetron sputtering process or the vacuum evaporation coating process. In the step S70, the barrier layer is a film layer coated on the reflective layer by a vacuum evaporation coating process. The components of the barrier layer 105 mainly include Au, and the remaining components include one or more of Cr/Pt/Ti/Ni/Sn elements. In step S80, the insulating layer 106 is a film layer deposited on the barrier layer 105 using the plasma enhanced vapor deposition process. In step S90, an N-type pad 1071 and a P-type pad 1072 are deposited.

Further, in this embodiment, step S50 specifically includes the following steps.

In step S501: an SiO₂ film layer is firstly evaporated, and then a TiO₂ film layer is evaporated on the SiO₂ film layer.

In step S502: the above evaporation process is repeated until the SiO₂/TiO₂ laminated layer having a thickness of 1000 Å-2000 Å is formed.

In step S503: the SiO₂/TiO₂ laminated layer is dry etched through the ICP dry etching process, until etching to the lowermost TiO₂ layer.

In step S504: the SiO₂ film layer at the lowermost layer of the SiO₂/TiO₂ laminated layer is wet etched through the BOE wet etching process.

In the present embodiment, a pattern to be etched is prepared by using a yellow light uniform photoresist exposure and development process, and for two types of film layers, ICP dry etching process and BOE wet etching process are used respectively to complete the transfer of the pattern of the passivation layer.

Two methods are selected for the pattern etching process, because if only the dry etching process is used, when it is etched to the bottom of the passivation layer 103 is etched, the plasma may damage the surface of the PGaN after SiO₂ is completely etched, resulting in poor ohmic contact on the chip surface and a voltage rise. If only the wet etching process is used, the etching rates are different for SiO₂ and TiO₂ according to the BOE wet etching process. The etching rates of the two substances DBR are different, thus resulting in different cross-sections of the film layers, resulting in the existence of faults in the thickness of the metal coating, thereby affecting the current conduction and quality reliability performance detection of the chip, and causing an abnormal current leakage. In addition, the reflectivity is also improved by increasing the direct contact area of the passivation layer 103 and the P GaN in the ODR structure.

Further, in this embodiment, step S60 specifically includes the following steps.

In step S601: a layer of reflective metal is coated on the passivation layer by the magnetron sputtering process or the vacuum evaporation coating process.

In step S602: while coating the reflective metal, a Ti/Pt or TiW film layer is continuously deposited on the upper layer and covers the reflective metal.

In this embodiment, a layer of adhesion layer is firstly deposited, typically using Ti or Ni. However, since metals absorb light, TCO materials are preferred. In addition, Ag/Al/Rh, etc. can be selected as the layer of reflective metal. The coating can deposit the reflective metal with a thickness of 1000 Å-2000 Å by means of magnetron sputtering process or vacuum evaporation coating process. While coating the reflective metal, a Ti/Pt or TiW film layer is continuously deposited on the upper layer, covering the reflective metal, and inhibiting the migration of the reflective metal. Preferably, the Ag alloy component is selected, and doped with 2%-5% of the Pt component, so as to reduce the migration of the Ag. At the same time, the distance between the reflective layer and the edge of the Mesa is shortened, the area of the reflective layer is increased, and the brightness is improved.

Further, in this embodiment, step S80 specifically includes the following steps.

In step S801: a reflective layer of Al metal with a thickness of 500 Å-1000 Å is deposited on the barrier layer 105.

In step S802: a passivation film layer is deposited on the reflective layer of Al metal.

In step S803: an aperture is prepared on the passivation film layer by etching through the yellow light uniform photoresist exposure and development process.

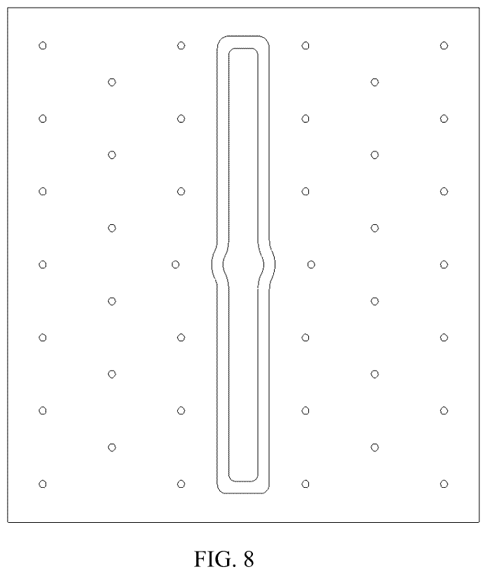

Referring to FIG. 8, in step S80, the plasma enhanced vapor deposition process is used to deposit the passivation film layer across the wafer surface. In this step, the material of the the passivation film layer is selected from any one or more laminated layers of silicon dioxide, silicon nitride and aluminum oxide, or deposited coated films of silicon dioxide/silicon nitride and silicon dioxide/silicon nitride/aluminum oxide, with the deposition temperature of 250° C.-300° C., and the deposition thickness of 5000 Å-8000 Å. For example, in the present embodiment, the passivation film layer is silicon dioxide, an independent light emitting unit structure is formed by performing deep etching firstly, and then a silicon dioxide layer is manufactured on the entire surface of the wafer. The insulation property of silicon dioxide is used to prevent the occurrence of electrical leakage caused by direct exposure of the material of the epitaxial layer after the product is cut.

In addition, by means of the yellow light uniform photoresist exposure and development process, the aperture is prepared on the passivation film layer. Except for the aperture area of the passivation film layer, full coverage of the Al emitting layer is formed, thereby further improving the brightness.

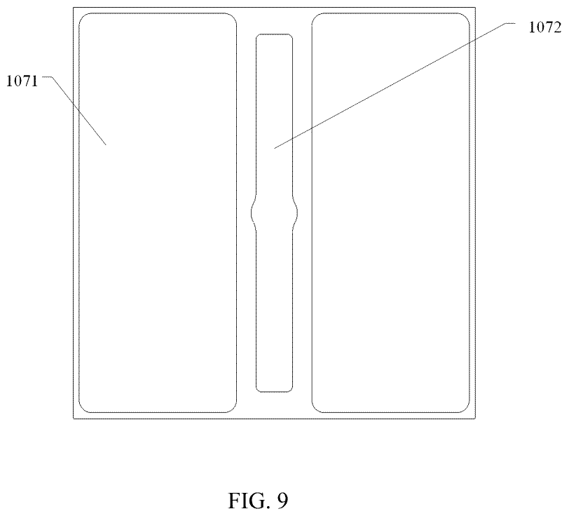

Further, referring to FIG. 9, in this embodiment, step S90 specifically includes the following steps.

In step S901: the pad is patterned by using the yellow light uniform photoresist exposure and development process.

In step S902: the negative adhesive base film is removed by using an Asher process;

In step S903: Cr/Pt/Ni/Pt/Ni/AuSn is deposited by using an E-Beam device after the wafer source is cleaned by spinning;

In step S904: removing the photoresist using an alkaline degumming liquid.

Here, it should be noted that the thickness of AuSn is 3 μm-4 μm.

Finally, it should be noted that the foregoing embodiments are merely intended for describing the technical solutions of the present disclosure, but not intended to limit the present disclosure. Although the present disclosure is described in detail with reference to the foregoing embodiments, persons of ordinary skill in the art should understand that they may still make modifications to the technical solutions described in the foregoing embodiments or make equivalent replacements to some technical features thereof. These modifications or replacements do not make the essence of the corresponding technical solutions depart from the spirit and scope of the technical solutions of the embodiments of the present disclosure. The objectives, technical solutions, and beneficial effects of the present disclosure are further described in detail through the foregoing specific embodiments. It should be understood that the foregoing descriptions are merely specific embodiments of the present disclosure, but are not intended to limit the present disclosure. Any modification, equivalent replacement, or improvement made within the spirit and principle of the present disclosure shall belong to the scope of protection of the present disclosure.

1. A light emitting element, comprising:
a substrate, and a light emitting structure, a current spreading layer, a passivation layer, a reflective layer, a barrier layer, an insulating layer and a pad which are sequentially grown on the substrate;
wherein the pad comprises two N-type pads and one P-type pad, the P-type pad being located between the two N-type pads, an area proportion of the N-type pad is greater than that of the P-type pad, and a plurality of N-type holes are uniformly arranged at an end surface of each of the N-type pads, so as to provide more current channels between a P electrode and an N electrode, so that current spreading between the P electrode and the N electrode is sufficient, thereby reducing a voltage between the P electrode and the N electrode.

2. The light emitting element according to claim 1, wherein the plurality of N-type holes are arranged in a plurality of columns on an end surface of the N-type pad, and the N-type holes, in two adjacent columns are arranged in a staggered manner, so that the N-type holes are distributed uniformly on the end surface of the N-type pad.

3. The light emitting element according to claim 1, wherein the area proportion of the N-type pad is more than 10 times of that of the P-type pad, so that a plurality of N-type holes can be provided at the end surface of the N-type pad to increase provide more current channels between the P electrode and the N electrode.

4. The light emitting element according to claim 3, wherein apertures of the current spreading layer and apertures of the passivation layer are arranged in a staggered manner, so as to improve the brightness.

5. The light emitting element according to claim 4, wherein a component of reflective metal for forming the reflective layer comprises Ag alloy and 2%-5% Pt component for improving brightness.

6. A manufacturing method for a light emitting element, the manufacturing method comprising:
sequentially growing an N-type semiconductor layer, an active layer and a P-type semiconductor layer on a substrate so as to form an epitaxial layer;
etching an isolation channel between adjacent chiplets, so that each chiplet is completely isolated on the epitaxial layer, thereby forming separate units;
etching a groove extending to the N-type semiconductor layer on the P-type semiconductor layer by means of inductive coupling plasma etching process, so as to form an N-type conductive region;
forming a current spreading layer on the P-type semiconductor layer;
forming a passivation layer on the current spreading layer;
forming a reflective layer on the passivation layer;
forming a barrier layer on the reflective layer;
forming an insulating layer on the barrier layer;
depositing an N-type pad and a P-type pad.

7. The manufacturing method for the light emitting element according to claim 6, wherein the step of forming a passivation layer on the current spreading layer comprises:
firstly evaporating an SiO₂ film layer, and then evaporating a TiO₂ film layer on the SiO₂ film layer;
repeating the evaporating process until a SiO₂/TiO₂ laminated layer having a thickness of 1000 Å-2000 Å is formed;
dry etching the SiO₂/TiO₂ laminated layer through an ICP dry etching process, until etching to the lowermost TiO₂ layer;
wet etching an SiO₂ film layer at the lowermost layer of the SiO₂/TiO₂ laminated layer through a BOE wet etching process.

8. The manufacturing method for the light emitting element according to claim 7, wherein the step of forming the reflective layer on the passivation layer comprises:
coating a layer of reflective metal on the passivation layer by a magnetron sputtering process or a vacuum evaporation coating process;
while coating the reflective metal, continuously depositing a Ti/Pt or TiW film layer on an upper layer and covering the reflective metal.

9. The manufacturing method for the light emitting element according to claim 8, wherein the step of forming an insulating layer on the barrier layer comprises:
depositing a passivation film layer using a plasma enhanced vapor deposition process at 250° C. to 300° C.;
depositing a reflective layer of Al metal with a thickness of 500 Å-1000 Å on the passivation film layer;
depositing the passivation film layer on the reflective layer of Al metal;
making an aperture on the passivation film layer by etching through the yellow light uniform photoresist exposure and development process.

10. The manufacturing method for the light emitting element according to claim 9, wherein the step of depositing an N-type pad and a P-type pad comprises:
patterning the pad by using the yellow light uniform photoresist exposure and development process;
removing a negative adhesive base film by using an Asher process;
depositing Cr/Pt/Ni/Pt/Ni/AuSn using an E-Beam device after a wafer source is cleaned by spinning;
removing photoresist using an alkaline degumming liquid.
